(19) United States
(12) Patent Application Publication
(10) Pub. No.: US 2026/0231363 A1
(43) Pub. Date: Aug. 6, 2026

(54) INDUCED CAPILLARY ACTION TO CONTROL A FLUID FLOW IN AN INFORMATION HANDLING SYSTEM

(71) Applicant: DELL PRODUCTS L.P., Round Rock, TX (US)

(72) Inventors: Brennan Seal, Austin, TX (US); Trevor Dawson, Austin, TX (US); Patrick Illingworth, Austin, TX (US)

(21) Appl. No.: 19/044,111

(22) Filed: Feb. 3, 2025

(51) Int. Cl. H05K 7/20; G06F 1/20

(52) U.S. Cl. CPC H05K 7/20272; G06F 1/20; G06F 2200/201

(57) ABSTRACT

A fluid flow control subsystem for controlling fluid flows within a liquid-cooled information handling system includes a structure that extends upward from a chassis base of the liquid-cooled information handling system. A capillary action-inducing flange extends outwardly from a bottom portion of the structure and forms a narrow gap above the chassis base. Responsive to a fluid leak within the liquid-cooled information handling system, the capillary action-inducing flange causes a capillary flow to draw leaked fluid in a predetermined direction.

### FIELD OF THE DISCLOSURE

The present disclosure generally relates to information handling systems, and more particularly relates to liquid cooling of an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A fluid flow control subsystem within a liquid-cooled information handling system includes a structure that extends upward from a chassis base of the liquid-cooled information handling system. A capillary action-inducing flange extends outwardly from the bottom portion of the structure and forms a narrow gap above the chassis base. Responsive to a fluid leak within the liquid-cooled information handling system, the capillary action-inducing flange causes a capillary flow to draw leaked fluid in a predetermined direction.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is perspective view of an example liquid cooling subsystem for liquid cooling of an information handling system according to at least one embodiment of the present disclosure;

FIG. 2 is a partially exploded perspective view of an example fluid flow control subsystem for controlling flows of leaked coolant within a liquid-cooled information handling system according to at least one embodiment of the present disclosure;

FIG. 3 is cross-sectional view of an example capillary action-inducing flange extending above a chassis base to form a gap between the base and flange according to at least one embodiment of the present disclosure;

FIGS. 4A and 4B, respectively, are a perspective view and a cross-sectional view of an example fluid flow control subsystem according to at least one embodiment of the present disclosure;

FIGS. 5A and 5B, respectively, are a perspective view and a side view of an example fluid flow control subsystem according to at least one embodiment of the present disclosure;

FIG. 6 is a perspective view of an example capillary action-inducing flange extending rising at a predetermined angle relative to a chassis base according to at least one embodiment of the present disclosure;

FIG. 7 is a flow diagram of an example method 700 of controlling fluid flows within a liquid-cooled information handling system according to at least one embodiment of the present disclosure; and

FIG. 8 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or sub-system. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a computer, server (such as a blade server or rack server), a network storage device, or any other such device and may vary in size, shape, performance, functionality, and price. The information handling system may include random access memory (RAM), one or more processing resources such as a central processing unit (CPU), graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

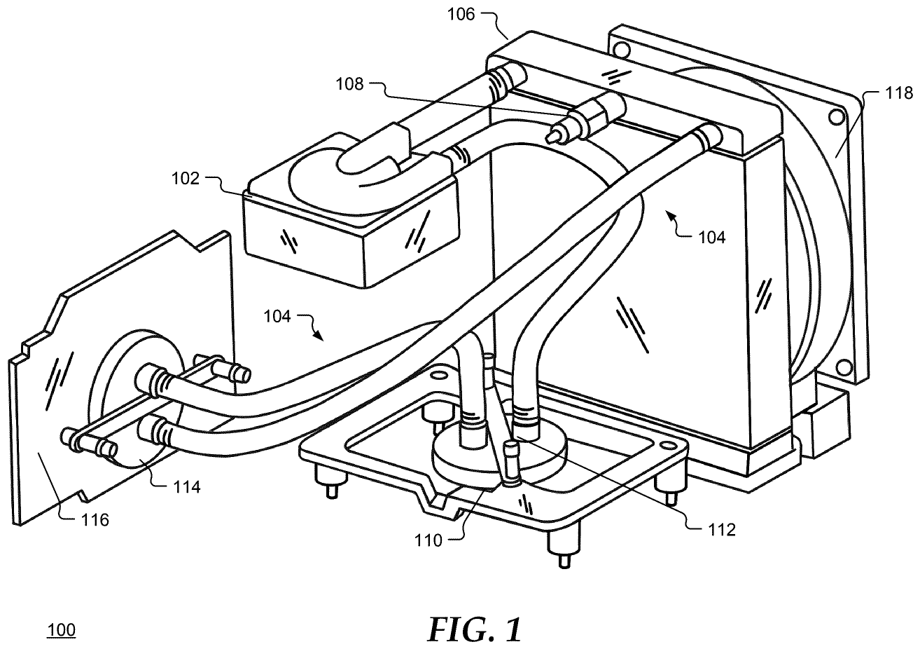

As the processing power of information handling systems continues to increase, the use of liquid cooling is expected to become more common owing to certain advantages that liquid cooling offers over other types of cooling. Referring to FIG. 1, an example liquid cooling system 100 is illustrated according to at least one embodiment of the present disclosure. Liquid cooling system 100 illustratively includes pump 102, tubing 104, heat exchanger 106, coolant port 108, CPU cold plate 110, clamp 112, GPU cold plate 114, memory heatsink 116, and fan 118. Pump 102 circulates a coolant such as water or other liquid (e.g., water plus additives) through tubing 104 and heat exchanger 106 to the components of the information handling system, including memory, CPU and/or GPU, as well as other components. The coolant circulates coolant-absorbing heat from the components and cooling the components via the cold plates-in a closed loop within the housing of the information handling system.

Notwithstanding the advantages of liquid cooling, there is the possibility that one or more components of the liquid cooling system may develop leaks over time due to vibration, thermal cycles, aging, misalignment of heat exchangers or cold plates, or the like. Any leak that exposes the components of the information handling system to liquid can cause corrosion or damage to the circuitry within the system's housing. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack.

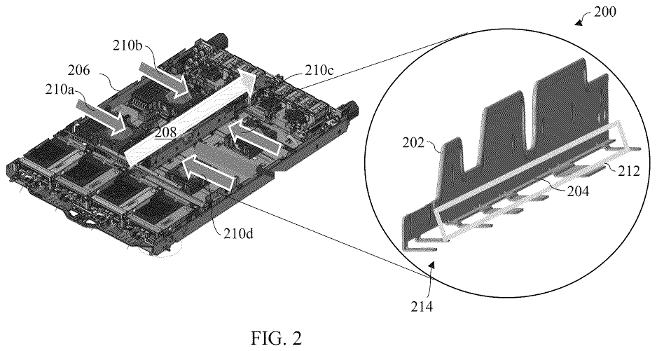

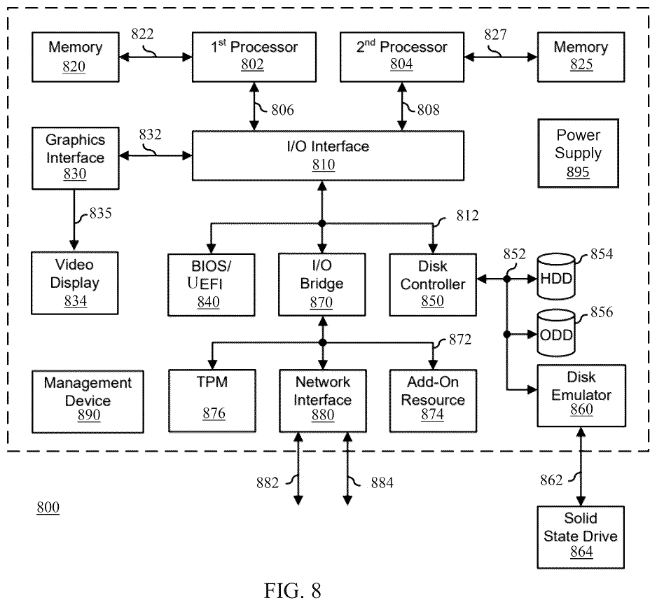

FIG. 2 illustrates a fluid flow control subsystem 200 within a liquid-cooled information handling system, such as information handling system 800 of FIG. 8, according to at least one embodiment of the present disclosure. Illustratively, fluid flow control subsystem 200 includes structure 202 and capillary action-inducing flange 204. Structure 202 extends upwardly from the base of chassis 206 of the information handling system. Capillary action-inducing flange 204 extends outwardly from the bottom portion of the structure 202. Structure 202 may extend substantially vertically and perpendicular from the base of chassis 206. Capillary action-inducing flange 204 extends in a substantially perpendicular direction relative to structure 202 so that it is parallel with and above the base of chassis 206, thereby forming a relatively narrow gap above the base. Operatively, in response to a leak of coolant fluid within chassis 206, capillary action-inducing flange 202 causes a capillary flow in predetermined direction 208. In certain embodiments described below, capillary action-inducing flange 202 captures flows 210a, 210b, 210c, and 210d of fluid that may naturally flow toward the center of chassis 206 due to an inherent sag that at least slightly lowers the center of the base relative to the outlying regions of chassis 206 and creates a downward slope toward the center.

Illustratively in FIG. 2, capillary action-inducing flange 204 is highlighted by rectangular enclosure 212, which is included in FIG. 2 only for illustrative purposes and does not represent a physical component. In certain embodiments, multiple extensions 214, which are optional physical components, may be interspersed along the edge of capillary action-inducing flange 204, extending down and parallel with the base of chassis 206 for fastening structure 202 to the base. In certain embodiments, structure 202 is a mechanical support brace, which may extend vertically and substantially perpendicular to the base of chassis 206. Structure 202, in some embodiments, may extend lengthwise along the base of chassis 206 and may be centered so that it is substantially evenly spaced between the respective edges of chassis 206.

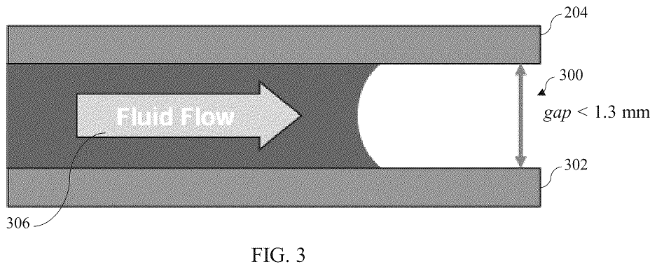

FIG. 3 illustrates gap 300, which is created between portions of chassis base 302 and capillary action-inducing flange 204 extending outwardly from the bottom portion of structure 202 and above the chassis base according to at least one embodiment of the present disclosure. A capillary action may be induced in gap 300. A capillary action, as is well-known, is the flow of a fluid through a narrow space without the assistance of gravity or other external forces. Rather, the capillary action is due to the adhesive forces that attract the molecules of a fluid to a surface of an enclosure being greater than the cohesive forces attracting the molecules to one another. In various embodiments, gap 300, as formed between capillary action-inducing flange 204 and chassis base 302, may be a narrow gap of at least 0.4 millimeters (mm) and no more than 1.3 mm. In certain examples, the capillary action induces a fluid flow 306. The induced capillary action, especially if maximized, may pull fluid flow 306, directing it to a predetermined region within the chassis of the information handling system.

In certain examples, leaked coolant fluid may be drawn by the induced capillary action away from different components of an information handling system, such as information handling system 800 of FIG. 8. These components of information handling system may include, but are not limited to, a random access memory (RAM), processing resources (e.g., CPU, GPU), hardware and/or software control logic, read only memory (ROM) and/or other types of nonvolatile memory, and/or other predetermined components illustrated in FIG. 8. In some examples, leaked coolant fluid may be drawn by capillary action to the back of the chassis or another region of the information handling system from which the leaked coolant fluid may be easily removed while mitigating potential damage to the components of the information handling system. An ability to control or at least influence the fluid flow, moreover, provides predictability regarding the likely path that coolant fluid would take were it to leak from the information handling system's liquid cooling apparatus or subsystem and may be used to minimize damage resulting from the leak.

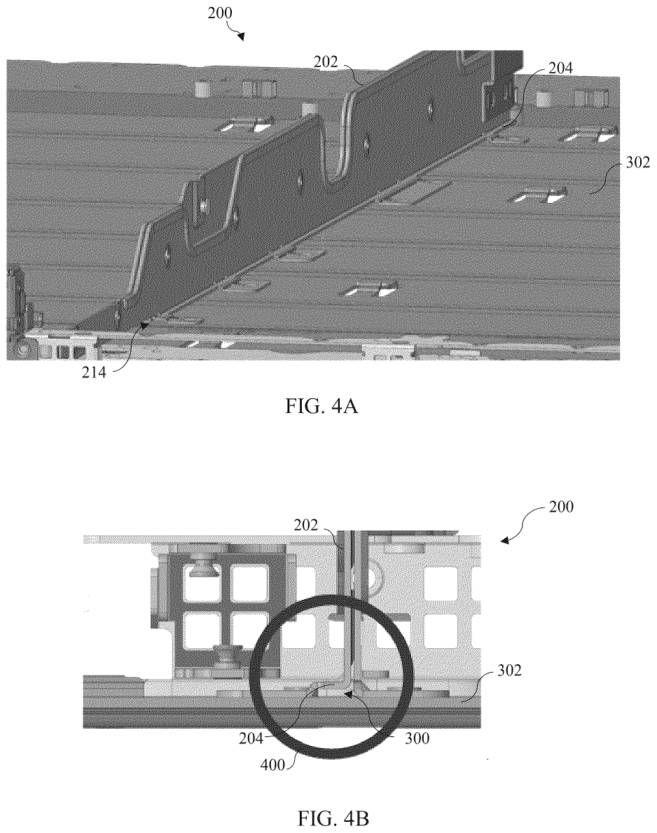

FIGS. 4A and 4B provide additional views of fluid flow control subsystem 200 according to at least one embodiment of the present disclosure. FIG. 4A is a perspective view of an embodiment in which structure 202 is fastened to chassis base 302 by multiple extensions 214, which may be interspersed along the edge of capillary action-inducing flange 204. FIG. 4B is a cross-sectional view of fluid flow control subsystem 200. Circle 400 is not a physical component but is interposed merely to highlight gap 300, which is created between chassis base 302 and capillary action-inducing flange 204.

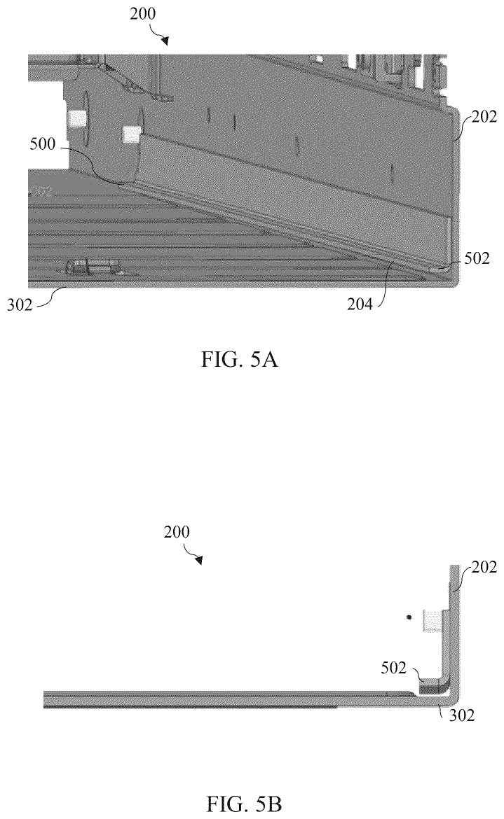

FIGS. 5A and 5B illustrate another embodiment of a fluid flow control subsystem 200 according to at least one embodiment of the present disclosure. Illustratively, capillary action-inducing flange 204 is fastened to structure 202, having first edge 500 and second edge 502. Structure 202 extends in a substantially vertical direction upward from chassis base 302. Capillary action-inducing flange 204 extends continuously along a side of structure 202. In certain embodiments, as capillary action-inducing flange 204 extends continuously from first edge 500 to second edge 502, it rises from the first edge to the second edge at a predetermined angle relative to chassis base 302.

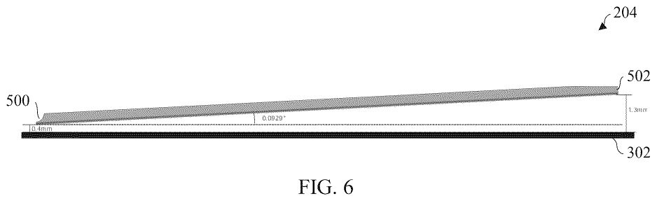

FIG. 6 illustrates capillary action-inducing flange 204 having first edge 500 and second edge 502 according to at least one embodiment of the present disclosure. Capillary action-inducing flange 204 extends continuously from first edge 500 to second edge 502, rising relative to chassis base 302 at a predetermine angle. In certain embodiments, the predetermined angle is approximately 0.09029°. First edge 500, in an example, is 0.4 mm above chassis base 302 and second edge 502 is 1.3 mm above chassis base 302. In this example, the angle of approximately 0.09029° may provide the height difference between 0.4 mm at first edge 500 and 1.3 mm at second edge 502, and the first and second edges may approximately 555 mm apart. It has been understood by the inventors of the present disclosure that a 1.3 mm gap between second edge 502 and chassis base 302, as illustrated in FIG. 6, is a gap dimension at which fluid starts to form a capillary bridge with the surface above it and starts to wick down the angled surface. The larger opening may be 1.3 mm or less above the surface of chassis base 302, and capillary action-inducing flange 204 may be angled down to pull the fluid along the length of the surface.

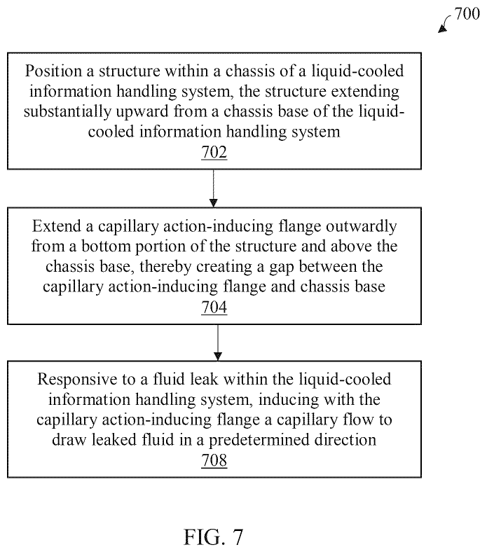

FIG. 7 is a flow diagram of example method 700 for controlling fluid flows within a liquid-cooled information handling system according to at least one embodiment of the present disclosure. It will be readily appreciated that not every method step set forth in this flow diagram is always necessary, and that certain steps of the methods may be combined, performed simultaneously, in a different order, or perhaps omitted, without varying from the scope of the disclosure. Method 700 may be performed by a fluid flow control subsystem having certain features of fluid flow control subsystem 200 described with reference to FIGS. 2-6.

At block 702, a structure is positioned within a chassis of a liquid-cooled information handling system. The structure is positioned to extend upward from a chassis base of the liquid-cooled information handling system. In certain examples, the structure may be a mechanical support brace extending perpendicular to the chassis base to provide mechanical support to the chassis.

At block 704, a capillary action-inducing flange is extended outwardly from a bottom portion of the structure and above the chassis base. The capillary action-inducing flange creates a narrow gap between the capillary action-inducing flange and the chassis base. In certain embodiments, the narrow gap may be at least 0.4 mm but no more than 1.3 mm.

At block 706, responsive to a fluid leak within the liquid-cooled information handling system, the capillary action-inducing flange causes a capillary flow to draw leaked fluid in a predetermined direction. The predetermined direction of the capillary flow may be substantially away from processing resources (e.g., CPUs, GPUs, memory) contained with a chassis of the liquid-cooled information handling system.

In certain embodiments, the structure extending upwardly from the chassis base is a mechanical support brace that is approximately centered relative to respective edges of the chassis base. The center portion of the chassis base may be relatively lower than the outward regions nearer the edges of the chassis base, causing a downward slope toward the center. Coolant leaked from a liquid cooling apparatus or subsystem may result in naturally occurring sag flows as the coolant flows along the downward slope toward the center. Accordingly, with the mechanical support brace approximately centered and extending lengthwise between the front and back of the chassis, the natural sag flows of leaked fluid may be captured in the narrow gap created by extending the capillary action-inducing flange over the chassis base.

The capillary action-inducing flange, in some embodiments, has a first edge and a second edge and extends continuously along the side of the structure, rising from the first edge to the second edge at a predetermined angle relative to the chassis base. With the structure extending lengthwise along an approximate center of the chassis base, the first edge of the flange may be closest to the front of the chassis base and the second edge of the flange may be closest to the back of the chassis base and may direct the capillary flow toward the back of the chassis base. In some embodiments the predetermined angle is 0.0929° approximately. The first edge of the capillary action-inducing flange, in certain embodiments, is positioned 0.4 mm above the chassis base. In certain embodiments, the second edge of the capillary action-inducing flange is positioned 1.3 mm above the chassis base.

FIG. 8 shows a generalized embodiment of an information handling system 800 according to an embodiment of the present disclosure. Information handling system 800 may be substantially like one having a liquid cooling apparatus or subsystem such as that described in FIG. 1 and that also includes a fluid flow control subsystem such as that described with reference to FIGS. 2-6. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 800 can be a computer, a network server, a network storage device, a switch router or other network communication device, or any other suitable device sufficiently sized to accommodate a liquid cooling apparatus or subsystem. Further, information handling system 800 can include processing resources for executing machine-executable code, such as a central processing unit (CPU), a programmable logic array (PLA), an embedded device such as a System-on-a-Chip (SoC), or other control logic hardware. Information handling system 800 can also include one or more computer-readable medium for storing machine-executable code, such as software or data. Additional components of information handling system 800 can include one or more storage devices that can store machine-executable code, one or more communications ports for communicating with external devices, and various input and output (I/O) devices, such as a keyboard, a mouse, and a video display. Information handling system 800 can also include one or more buses operable to transmit information between the various hardware components.

Information handling system 800 can include devices or modules that embody one or more of the devices or modules described below and operates to perform one or more of the methods described below. Information handling system 800 includes a processors 802 and 804, an input/output (I/O) interface 810, memories 820 and 825, a graphics interface 830, a basic input and output system/universal extensible firmware interface (BIOS/UEFI) module 840, a disk controller 850, a hard disk drive (HDD) 854, an optical disk drive (ODD) 856, a disk emulator 860 connected to an external solid state drive (SSD) 864, an I/O bridge 870, one or more add-on resources 874, a trusted platform module (TPM) 876, a network interface 880, a management device 890, and a power supply 895. Processors 802 and 804, I/O interface 810, memory 820, graphics interface 830, BIOS/UEFI module 840, disk controller 850, HDD 854, ODD 856, disk emulator 860, SSD 864, I/O bridge 870, add-on resources 874, TPM 876, and network interface 880 operate together to provide a host environment of information handling system 800 that operates to provide the data processing functionality of the information handling system. The host environment operates to execute machine-executable code, including platform BIOS/UEFI code, device firmware, operating system code, applications, programs, and the like, to perform the data processing tasks associated with information handling system 800.

In the host environment, processor 802 is connected to I/O interface 810 via processor interface 806, and processor 804 is connected to the I/O interface via processor interface 808. Memory 820 is connected to processor 802 via a memory interface 822. Memory 825 is connected to processor 804 via a memory interface 827. Graphics interface 830 is connected to I/O interface 810 via a graphics interface 832 and provides a video display output 836 to a video display 834. In a particular embodiment, information handling system 800 includes separate memories that are dedicated to each of processors 802 and 804 via separate memory interfaces. An example of memories 820 and 830 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 840, disk controller 850, and I/O bridge 870 are connected to I/O interface 810 via an I/O channel 812. An example of I/O channel 812 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 810 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 840 includes BIOS/UEFI code operable to detect resources within information handling system 800, to provide drivers for the resources, initialize the resources, and access the resources. BIOS/UEFI module 840 includes code that operates to detect resources within information handling system 800, to provide drivers for the resources, to initialize the resources, and to access the resources.

Disk controller 850 includes a disk interface 852 that connects the disk controller to HDD 854, to ODD 856, and to disk emulator 860. An example of disk interface 852 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 860 permits SSD 864 to be connected to information handling system 800 via an external interface 862. An example of external interface 862 includes a USB interface, an IEEE 4394 (Firewire) interface, a proprietary interface, or a combination thereof. Alternatively, solid-state drive 864 can be disposed within information handling system 800.

I/O bridge 870 includes a peripheral interface 872 that connects the I/O bridge to add-on resource 874, to TPM 876, and to network interface 880. Peripheral interface 872 can be the same type of interface as I/O channel 812 or can be a different type of interface. As such, I/O bridge 870 extends the capacity of I/O channel 812 when peripheral interface 872 and the I/O channel are of the same type, and the I/O bridge translates information from a format suitable to the I/O channel to a format suitable to the peripheral channel 872 when they are of a different type. Add-on resource 874 can include a data storage system, an additional graphics interface, a network interface card (NIC), a sound/video processing card, another add-on resource, or a combination thereof. Add-on resource 874 can be on a main circuit board, on separate circuit board or add-in card disposed within information handling system 800, a device that is external to the information handling system, or a combination thereof.

Network interface 880 represents a NIC disposed within information handling system 800, on a main circuit board of the information handling system, integrated onto another component such as I/O interface 810, in another suitable location, or a combination thereof. Network interface device 880 includes network channels 882 and 884 that provide interfaces to devices that are external to information handling system 800. In a particular embodiment, network channels 882 and 884 are of a different type than peripheral channel 872 and network interface 880 translates information from a format suitable to the peripheral channel to a format suitable to external devices. An example of network channels 882 and 884 includes InfiniBand channels, Fibre Channel channels, Gigabit Ethernet channels, proprietary channel architectures, or a combination thereof. Network channels 882 and 884 can be connected to external network resources (not illustrated). The network resource can include another information handling system, a data storage system, another network, a grid management system, another suitable resource, or a combination thereof.

Management device 890 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 800. In particular, management device 890 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 800, such as system cooling fans and power supplies. Management device 890 can include a network connection to an external management system, and the management device can communicate with the management system to report status information for information handling system 800, to receive BIOS/UEFI or system firmware updates, or to perform other task for managing and controlling the operation of information handling system 800.

Management device 890 can operate off a separate power plane from the components of the host environment so that the management device receives power to manage information handling system 800 when the information handling system is otherwise shut down. An example of management device 890 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 890 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed:

1. A fluid flow control subsystem within a liquid-cooled information handling system, the fluid flow control subsystem comprising:
a structure extending upward from a chassis base of the liquid-cooled information handling system; and
a capillary action-inducing flange extending outwardly from a bottom portion of the structure and forming a narrow gap above the chassis base,
wherein, responsive to a fluid leak within the liquid-cooled information handling system, the capillary action-inducing flange causes a capillary flow to draw a leaked fluid in a predetermined direction.

2. The fluid flow control subsystem of claim 1, wherein the predetermined direction of the capillary flow is substantially away from processing resources contained within a chassis of the liquid-cooled information handling system.

3. The fluid flow control subsystem of claim 1, wherein the structure is a mechanical support brace.

4. The fluid flow control subsystem of claim 3, wherein the mechanical support brace is approximately centered relative to respective edges of the chassis base to capture natural sag flows of the leaked fluid.

5. The fluid flow control subsystem of claim 1, wherein the capillary action-inducing flange comprises a first edge and a second edge and extends along a side of the structure, rising from the first edge to the second edge at a predetermined angle relative to the chassis base.

6. The fluid flow control subsystem of claim 5, wherein the structure extends lengthwise from a front end to a back end of the chassis base such that the first edge of the flange is closest to the front end of the chassis base and the second edge of the flange is closest to a back end of the chassis base to direct the capillary flow toward the back end of the chassis base.

7. The fluid flow control subsystem of claim 5, wherein the predetermined angle is approximately 0.0929 degrees.

8. The fluid flow control subsystem of claim 1, wherein a first edge of the capillary action-inducing flange is positioned 0.4 millimeters above the chassis base.

9. The fluid flow control subsystem of claim 8, wherein a second edge of the capillary action-inducing flange is positioned 1.3 millimeters above the chassis base.

10. A method of controlling fluid flows within a liquid-cooled information handling system, the method comprising:
positioning a structure within a chassis of the liquid-cooled information handling system, wherein the structure extends upward from a chassis base of the liquid-cooled information handling system; and
extending a capillary action-inducing flange outwardly from a bottom portion of the structure and above the chassis base, thereby creating a narrow gap between the capillary action-inducing flange and chassis base,
wherein, responsive to a fluid leak within the liquid-cooled information handling system, the capillary action-inducing flange causes a capillary flow to draw a leaked fluid in a predetermined direction.

11. The method of claim 10, wherein the predetermined direction of the capillary flow is substantially away from processing resources contained with a chassis of the liquid-cooled information handling system.

12. The method of claim 10, wherein the structure is a mechanical support brace.

13. The method of claim 12, wherein the mechanical support brace is approximately centered relative to respective edges of the chassis base to capture natural sag flows of the leaked fluid.

14. The method of claim 10, wherein the capillary action-inducing flange comprises a first edge and a second edge and extending continuously along a side of the structure, rising from the first edge to the second edge at a predetermined angle relative to the chassis base.

15. The method of claim 14, wherein the structure extends lengthwise along an approximate center of the chassis base such that the first edge of the capillary action-inducing flange is closest to a front of the chassis base and the second edge of the capillary action-inducing flange is closest to a back of the chassis base to direct the capillary flow toward the back of the chassis base.

16. The method of claim 14, wherein the predetermined angle is approximately 0.0929 degrees.

17. The method of claim 14, wherein the first edge of the capillary action-inducing flange is positioned 0.4 millimeters above the chassis base.

18. The method of claim 14, wherein the second edge of the capillary action-inducing flange is positioned 1.3 millimeters above the chassis base.

19. An information handling system, comprising:
a chassis having a chassis base;
a memory contained within the chassis;
one or more processing resources contained withing the chassis and operatively coupled with the memory via a bus; and
a flow control subsystem including:
a structure extending upward from a chassis base of the information handling system; and
a capillary action-inducing flange extending outwardly from a bottom portion of the structure and forming a narrow gap above the chassis base,
wherein, responsive to a fluid leak within the information handling system, the capillary action-inducing flange causes a capillary flow to draw a leaked fluid in a predetermined direction.

20. The information handling system of claim 19, wherein the structure is a mechanical support brace, and wherein the mechanical support brace is approximately centered relative to respective edges of the chassis base to capture natural sag flows of the leaked fluid.
